(19) United States
(12) Patent Application Publication
(10) Pub. No.: US 2020/0271739 A1
(43) Pub. Date: Aug. 27, 2020

(54) RADIO FREQUENCY COIL UNIT FOR MAGNETIC RESONANCE IMAGING AND RADIO FREQUENCY COIL

(71) Applicant: SUZHOU MEIKE MEDICAL TECHNOLOGY CO., LTD., Jiangsu (CN)

(72) Inventor: Huabin ZHU, Jiangsu (CN)

(21) Appl. No.: 16/614,273

(22) PCT Filed: Nov. 28, 2017
(86) PCT No.: PCT/CN2017/113383

§ 371 Date: Nov. 15, 2019

(30) Foreign Application Priority Data
Mar. 23, 2017 (CN) 201710177535.X

(51) Int. Cl. G01R 33/34; G01R 33/36; G01R 33/561

(52) U.S. Cl. CPC G01R 33/34092; G01R 33/365; G01R 33/3621; G01R 33/3664; G01R 33/3628; G01R 33/5612

(57) ABSTRACT

The invention discloses an RF coil element and an RF coil for magnetic resonance imaging, wherein the RF coil element is connected with an active loss circuit capable of actively dissipating and absorbing RF power in the RF coil element to decrease the Q value of the coil element. The active loss circuit is connected to the coil element to absorb the RF power in the coil element to decrease the Q value of the coil element, so that the coupling degree (correlation coefficient) between every two elements of an array coil formed by the coil elements is decreased, thus improving the parallel transmission (pTX) performance and the uniformity of a magnetic resonance RF transmission field.

### BACKGROUND OF THE INVENTION

### Technical Field

The invention belongs to the field of magnetic resonance imaging, and particularly relates to an RF coil element and an RF coil for magnetic resonance imaging.

### Description of Related Art

The performance of radio frequency (RF) coils that serve as the key constituent part of magnetic resonance systems have a significant influence on the overall performance, security and image quality of magnetic resonance products. The RF coils are responsible for exciting and acquiring magnetic resonance signals in the MRI system in such a manner that an RF excitation field (B1 Field) generated by an RF transmitter coil excites nucleuses (generally hydrogen nucleuses) of a sample, with a non-zero spin, in a fixed main magnetic field (B0 Field) to generate a nuclear magnetic resonance (NMR) signal and then a magnetic resonance RF signal is received and acquired by a receiver coil. Therefore, magnetic resonance RF coils are typically classified into transmitter-only coils, receiver-only coils, and transceiver coils by function.

In actual use, a transmitter-only coil (TX Only) and a receiver-only coil (RX Only) are usually adopted to fulfill excitation and reception of RF signals; or, a transceiver coil (TxRx coil) is adopted to fulfill the same purpose.

Because the signal to noise ratio (resolution) of magnetic resonance images is generally in direct proportion to the intensity of the main magnetic field (B0 Field), one significant development direction of the magnetic resonance technology is to constantly increase the magnetic field intensity of magnets. In terms of the intensity of the main magnetic field, there are typically four types of magnetic resonance machines: low field: represented by permanent magnets, B0≤0.5T (T is an abbreviation for magnetic field intensity Telsa); medium field: represented by 1.0T and 1.5T superconducting magnets; high field: represented by 3.0T superconducting magnets; ultra-high field: represented by 4.7T, 7.0T and 11.7T superconducting magnet, or superconducting magnets with even higher fields.

A key technical indicator of the RF coils in the magnetic resonance machines is the center frequency which is accurately in direct proportion to the intensity of the main magnetic field (B0 Field), that is, the higher the intensity of the B0 field, the higher the center frequency f₀ of the coils. The transmitter coils also have another three important performance indicators: first, the uniformity of the RF transmission field (B1 field), which is also of great importance; second, the transmission efficiency of the coils; and finally, in consideration of the parallel transmission technique which is under development nowadays, the potential parallel transmission performance is also very important. The receiver coils have another two important indicators, namely the signal to noise ratio of reception and the parallel reception performance which are both closely related to the number of elements (number of channels) of the receiver coils. Therefore, the most crucial indicator for evaluating the performance of the receiver coils is the number of channels of the coils. Multi-channel coils are also referred to as array coils, such as 8-channel array coils.

The development of the magnetic resonance products and the constant increase of the magnetic field intensity and frequency have led to two principal negative properties of the RF field: the dielectric effect (RF vortexes) and the standing wave effect (resonance cavity effect), which in turn aggravates the non-uniformity of the RF excitation field and reduces the quality of magnetic resonance images. In addition, with the increase of the RF frequency, larger RF deposition (SAR) will be generated by the RF excitation field and may do harm to an inspected part, and the safety risk of inspected patients is increased. Therefore, the improvement on the uniformity of the RF transmission field and the decrease of SAR have become a solution to solving the development bottleneck of the ultra-high field RF technology, and improvements on the performance of the RF coils has become the top priority for promoting the development of ultra-high field MRI products.

From the above description, with the continuous increase of the intensity of the main magnetic field, the signal to noise ratio and the resolution of magnetic resonance images are constantly improved; however, the constant increase of the RF frequency aggravates the non-uniformity of the RF excitation field (B1 Field) and SAT problems relating to the safety of patients, which in turn severely restricts the further promotion of the intensity of the magnetic resonance field.

As for magnetic resonance at medium-low field intensities (≤1.5T), negative RF effects include the dielectric effect, the standing wave effect and the SAR problem, that is, the nonuniformity of B1 field and the SAR problem are not prominent yet. Technical solutions to these negative RF effects are quite mature, wherein the most common one is that: an overall birdcage body coil is used to excite a circularly-polarized B1 field, multiple local receiver-only array coils are adopted to control SAR within a safety range for patients and to excite a uniform B1 field at the same time, and the signal to noise ratio of reception of different parts of the patients is fully ensured through the multiple receiver-only array coils.

The negative RF effects start to appear when the magnetic field rises to a high field (represented by 3.0T), and in this case, the SAR safety needs to be monitored more strictly. The non-uniformity of the B1 field, represented by imaging of large parts such as the abdomen, becomes obvious and affects the image effect. Solutions to the high-field RF coils are also mature, and for most images of small body positions, solutions similar to those to medium-high fields can be adopted. For imaging of large body positions, two latest solutions have been put forwards: 1, elliptical polarization is adopted, that is, a birdcage body coil capable of being switched to be circularly-polarized or elliptically-polarized is adopted; 2, a double-channel parallel transmission technique is adopted, that is, two independent beams of RF energy pulses are output separately by two independent RF power amplifiers to generate two independent RF powers and phases, so as to drive two channels of an overall birdcage body coil. The two new solutions, particularly the latter one, can effectively improve the uniformity of the B1 field during imaging of large body positions, but the effect still remains unsatisfactory.

When the magnetic field rises to an ultra-high field (≥4.7T, typically 7.0T), the traditional mature overall birdcage body coil is not applicable anymore due to the fact that the SAR safety problem becomes more and more severe, in this case, the transmitter coil must be a local coil to effectively decease the SAR value, and in order to meet the requirement for the signal to noise ratio, the receiver coil should also be a local coil. In this case, if a transmitter-only coil and a receiver-only coil are adopted, these two coils will be very close to each other due to the fact that both coils are local coils and have similar sizes; in addition, the RF frequency corresponding to the ultra-high field is very high, the coupling degree of the two close coils is very high under the great influence of high-frequency distribution parameters, and consequentially, neither one of the two coils can work normally. Therefore, it is very difficult to technically implement the solution of two independent coils, and in most cases, one transceiver RF coil is nowadays adopted in the art.

Because the signal to noise ratio of images and the parallel reception performance of magnetic resonance are closely related to the number of channels of the receiver coils, most existing receiver coils are multi-channel array coils such as ultra-high field transceiver coils, and under the condition where the receiver coils are multi-channels array coils, the transmitter coils are also multi-channel array coils without exception. The multi-channel transceiver array coil and the multi-channel parallel transmission (pTX) technology which rises and becomes popular in the magnetic resonance field in recent years are the unique effective solution, that is internationally accepted and verified at present, to RF problems of ultra-high field magnetic resonance such as the SAR safety, the uniformity of B1 field, and selective excitation.

However, the multi-channel array coils have a common problem: the coupling degree between every two channels (elements). In general, the accumulative coupling degree between every two channels (elements) will become higher with the increase of the number of coil elements. The coupling between the elements has great influences on the overall performance of the coils. In the aspect of RF signal reception, these influences include the resonance frequency and impedance matching of the elements, the influence of the impedance matching on the noise coefficient of a pre-amplifier, algorithms adopted during magnetic resonance image synthesis according to signals received by the channels, and the parallel reception performance. In the aspect of RF transmission, these influences mainly include: the resonance frequency and impedance matching of the elements, the influence of the impedance matching on the transmission efficiency of the elements, the influence of the transmission efficiency of the elements on the uniformity of the transmission field, and the parallel transmission performance.

FIG. 1 shows the circuit principle of an existing coil element. As shown in FIG. 1, the existing coil element comprises an RF resonance circuit and a matching network used for converting the coil impedance across two terminals of the resonance circuit C_{P} into common characteristic impedance (generally 50Ω, 75Ω or 50Ω) to satisfy noise matching of a pre-amplifier or transmission impedance matching during transmission. During circuit implementation, a plurality of high-Q capacitors are connected in series between conductors to realize the resonance purpose; and the matching network is generally implemented by a high-Q capacitor or a high-Q inductor. For instance, the matching network of the RF coil element shown in FIG. 2 consists of a high-Q capacitor C_{S}.

Internal resistances exit in all components and conductors in actual use, certain equivalent internal resistances will still exist no matter how good the conductors and high-Q capacitors are, and the internal resistance is collectively referred to as R_{Conductor}; the conductor having the internal resistance removed is equivalent to an ideal inductor LConduct; and the resonance circuit can be regarded as an antenna which has an inevitable equivalent radiant resistance. During magnetic resonance imaging, a water phantom, a human body or a whole space placed in or near the resonance circuit can be regarded as an equivalent load resistor R_{Load} of the antenna, and thus, the RF coil element in FIG. 2 is actually equivalent to the circuit shown in FIG. 3.

It should be noted that R_{Conductor} and R_{Load} in FIG. 3 are not real resistors and are added to the equivalent circuit for the sake of a more visual and simpler circuit analysis. Traditionally, in order to improve the transmission efficiency or to increase the signal to noise ratio of reception, the influence of R_{Conductor} and R_{Load} should be minimized or avoided when the RF element is designed.

FIG. 1 to FIG. 3 show three equivalents or representatives of the existing RF coil element. For the sake of a convenient representation, the form in FIG. 2 is adopted to represent all these equivalents hereunder.

As mentioned above, before the magnetic field reaches a high field (B0≤3.0T), the transmitter coil and the receiver coil are generally two independent coils, wherein the transmitter coil is a birdcage circularly-polarized coil, and the receiver coil is a multi-channel array coil. Referring to FIG. 4 which shows a typical structure of the multi-channel receiver array coil, all elements are sequentially arrayed with the conductors of every two adjacent elements overlapping with each other, overlap inductive decoupling is adopted for the adjacent elements, and pre-amp decoupling instead of direct decoupling is adopted between secondary adjacent elements or even farther elements to meet requirements. In this way, almost all decoupling meets requirements, the area of the elements is large due to overlap, and the penetration capacity and penetration depth during reception are good.

However, as mentioned above, when the magnetic field rises to an ultra-high field (B0≥4.7T, typically 7.0T), the transmitter coil and the receiver coil are replaced by one local array coil; and when the coil is in a transmission mode, pre-amp decoupling between the elements is disabled, which in turn worsens the coupling (interference) between the elements, particularly between the secondary adjacent elements. In order to solve the problem of coupling between the elements of the transceiver array coil, the solution in FIG. 4 is replaced by the solution in FIG. 5: overlap inductive decoupling between the adjacent elements is not adopted anymore, instead, a distance is reserved between every two adjacent elements, and capacitive decoupling is adopted between the adjacent elements, so that the area of each element can be decreased, and the spacing between the secondary adjacent elements is increased, thus, reducing the coupling between the secondary adjacent elements. By adoption of such solution, the coupling between every two secondary adjacent elements is reduced; however, this solution still has the following two problems: 1, the decrease of the area of each coil element results in drastic reduction of the penetration capacity and penetration depth of the array coil during reception; 2, coupling still exists between the secondary adjacent elements and between next secondary adjacent elements, which means that the decoupling effect still remains unsatisfactory, and the problem of non-uniformity of the transmission field is not really solved yet.

No matter in the aspect of reception or in the aspect of transmission, the coupling between the elements of the RF coils (particularly the array coils) is a negative factor that should be reduced or even avoided. With the increase of the number of the elements of the array coils, the coupling becomes worse and more difficult to reduce or avoid, which in turn restricts the development, study and application of high-density array coils.

Compared with transmitter coils, the coupling problem of the receiver coils is not so severe due to the fact that an independent low-noise pre-amplifier is integrated in each coil element during reception to amplify a received weak magnetic resonance RF signal to reduce the signal to noise ratio loss in subsequent transmission and to fulfill a pre-amp decoupling function to effectively further weaken the coupling between every two adjacent elements of the receiver coils drastically, thus improving the reception performance of the coils.

The pre-amplifiers focus on noise matching instead of transmission matching of RF energy, so that the optimization of the noise coefficient and the decoupling function of the pre-amplifiers cannot be both taken into consideration unless when the amplifiers are designed. However, the transmitter coils focus on transmission matching of RF transmission energy and cannot fulfill an auxiliary decoupling function like the pre-amplifiers. Comparatively speaking, the problem of coupling between the elements of an array coil serving as a transmitter coil is more severe than that of an array coil serving as a receiver coil, which in turn leads to unsatisfactory coil transmission properties, such as the uniformity of the B1 field and the parallel transmission performance, of the transceiver coil, and this has become a common problem of magnetic resonance RF coils in ultra-high fields.

Coupling between elements is an inevitable negative factor when array coils, particularly multi-channel high-density coils, are designed. The coupling principle and decoupling method are analyzed and introduced below.

FIG. 6 shows a schematic diagram of two identical coil elements and coupling between the two identical coil elements. For the sake of model simplification, equivalent common resistors are omitted. Mutual inductance will be caused when the two coil elements are placed together, and the coefficient of mutual inductance is defined as K. Assume the current I1 in the left element in FIG. 6 is a normal working current, and I2 is an inductive current caused by mutual inductance, namely a result of coupling (interference). Herein, the coupling (interference) of element 1 on element 2 is defined as:

$${C}_{21} = \frac{I 2}{I 1} \qquad ( 1 )$$

Wherein, I1 is the normal working current of the left coil element, and I2 is an interference current generated by induction in the right coil element due to the presence of I1.

According to the mutual inductance principle, the induced electromotive force on the resonance circuit of the right coil element is:

ε2=jωk\sqrt{L1L2}·I1 (2)

The value of ε2 is related to the inductance and the coefficient of mutual inductance K of the two circuits, and the interference current I2 is:

$$I 2 = \frac{ɛ 2}{Z 2} = \frac{j ω k \sqrt{L 1 L 2}}{Z 2} • I 1 \qquad ( 3 )$$

By substituting (3) into (1), the coupling (interference) of element 1 on element 2 is:

$${C}_{21} = \frac{I 2}{I 1} = \frac{j ω k \sqrt{L 1 L 2}}{Z 2} \qquad ( 4 )$$

Because the two coil elements and the equivalent inductances L1 and L2 are constant, the value of C₂₁ depends on the coefficient of mutual inductance K and the impedance of the resonance circuit of the right coil element.

The decoupling method and principle are introduced as follows with reference to formula (3) and formula (4):

1. Decrease of the coefficient of mutual inductance K: a common method adopted to decrease the coefficient of mutual inductance K is overlap inductive decoupling. By adoption of this method, the magnetic flux generated by the left coil element and the magnetic flux generated by the right coil element are mutually counteracted, as shown in FIG. 7.

2. To counteract ε2 by means of another electromotive force generated by capacitive or inductive decoupling.

As shown in FIG. 8, a common capacitor CC is added between the two coil elements to generate a voltage which is equal and opposite to ε2 at the capacitor 2 terminal to keep the induced electromotive force at 0. The working principle of inductive decoupling is similar to this.

According to formula (3), another decoupling method adopted is to increase the circuit impedance Z2 of the right coil element in FIG. 8. The value of Z2 is first analyzed below.

FIG. 9 is an impedance analysis diagram of the resonance circuit of the right coil element in FIG. 8. For the sake of a brief analysis, Lconductor in FIG. 9 is set to L, and R_{(Conductor+Load)} in FIG. 9 is set to R, and in this case, the impedance Z2 in the resonance circuit is:

Z2=jωL+R+Z_{Match} (5)

Herein, a key concept of RF circuit matching is adopted: if there is, in an RF circuit, a face having two terminals with impedances in conjugate matching, the impedances across two terminals of any face are in conjugate matching. The first face is configured on the left side of the output terminatior, as can be seen, the impedances across the two terminals of the first face are both 50Ω and meet the conjugate matching condition, so that impedances across the terminals of the dotted line in FIG. 9 are also in conjugate matching, that is:

Z_{Match}=R−jωL (6)

The following formula can be obtained by substituting formula (6) into formula (5):

Z2=2R (7)

As can be seen from formula (7), the resonant impedance of the whole circuit can be increased by increasing the series resistance in the resonance circuit of the right coil element, and interference coupling of the left coil element on the right coil element in FIG. 8 is effectively reduced.

The Q value of the resonance circuit of the RF elements is:

$$Q = \frac{ω L}{R} \qquad ( 8 )$$

That is, if the series resistance R of the resonance circuits of the coil elements is increased, the Q value of the circuits is decreased correspondingly, and these two parameters are equivalent.

### BRIEF SUMMARY OF THE INVENTION

The objective of the invention is to provide an RF coil element and an RF coil for magnetic resonance imaging to effectively reduce the coupling between coil elements and to improve the parallel transmission performance, the uniformity of a transmission field and the penetration capacity during reception.

The technical solution adopted by the invention to fulfill the above object is as follows:

The invention provides an RF coil element for magnetic resonance imaging. The RF coil element for magnetic resonance imaging is connected with an active loss circuit which is able to actively dissipate and absorb RF power in the RF coil element to decrease the Q value of the coil element.

In some preferred embodiments of the invention, the active loss circuit is a resistor in series or parallel connection with a circuit component in the RF coil element.

In some preferred embodiments of the invention, the active loss circuit is a low-Q-value component in series or parallel connection with a circuit component in the RF coil element.

In some preferred embodiments of the invention, the active loss circuit is a conductor, with a conductivity smaller than that of copper, in series connection with a circuit component in the RF coil element.

In some preferred embodiments of the invention, the active loss circuit is an equivalent resistor module in series or parallel connection with a circuit component in the RF coil element.

In some preferred embodiments of the invention, a loss circuit on-off element used to turn on/off the active loss circuit is connected to the coil element.

In some preferred embodiments of the invention, the coil element is further connected with:

A frequency compensation circuit,

An impedance compensation circuit,

A frequency compensation circuit on-off element used to turn on/off the frequency compensation circuit, and

An impedance compensation circuit on-off element used to turn on/off the impedance compensation circuit.

In some preferred embodiments of the invention, the coil element comprises a resonance circuit and a matching network connected with the resonance circuit, wherein the active loss circuit is in series or parallel connection with a circuit component in the resonance circuit or the matching network, the frequency compensation circuit is in series or parallel connection with a circuit component in the resonance circuit, and the impedance compensation circuit is in series or parallel connection with a circuit component in the matching network.

In some preferred embodiments of the invention, the resonance circuit is a closed circuit formed by series connection of one or more conductors and one or more capacitors, and the matching network comprises a capacitor or an inductor.

In some preferred embodiments of the invention, the resonance circuit comprises at least two capacitors which are connected in series, the active loss circuit is connected in series with a first diode and is then connected in parallel with one capacitor in the resonance circuit, a first inductor is connected in series with a second diode and is then connected in parallel with another capacitor in the resonance circuit, the first diode constitutes the loss circuit on-off element, and the second diode constitutes the frequency compensation circuit on-off element.

In some preferred embodiments of the invention, the active loss circuit is connected in series with a second inductor and a third diode and is then connected in parallel with one capacitor in the resonance circuit, the second inductor constitutes the frequency compensation circuit, and the third diode constitutes the frequency compensation circuit on-off element and the loss circuit on-off element.

In some preferred embodiments of the invention, two terminals of the active loss circuit and the second inductor are connected in parallel with a first capacitor, and the second inductor and the first capacitor constitute the frequency compensation circuit jointly.

In some preferred embodiments of the invention, the second capacitor is connected in series with a fourth diode and is then connected in parallel with the capacitor or inductor in the matching network, the second capacitor constitutes the impedance compensation circuit, and the fourth diode constitutes the impedance compensation circuit on-off element.

The invention provides an RF coil for magnetic resonance imaging. The RF coil for magnetic resonance imaging is an array coil and comprises at least one RF coil element mentioned above.

Preferably, the RF coil is a transceiver-only RF array coil, a receiver-only RF array coil, or a transceiver RF array coil.

The invention further provides another RF coil for magnetic resonance imaging. The RF coil for magnetic resonance imaging is a birdcage coil and is connected with an active loss circuit used for actively dissipating and absorbing RF power in the RF coil to decrease the Q value of the coil.

Preferably, the active loss circuit is connected in series or parallel with a capacitor in the RF coil.

The invention has the following beneficial effects:

1. The active loss circuit capable of actively dissipating and absorbing the RF power in the RF coil element to decrease the Q value of the RF coil element is arranged in the RF coil element, and the active loss circuit actively absorbs the RF power in the RF coil element to decrease the Q value of the RF coil element, so that the series impedance of the resonance circuit is improved, which in turn decreases the coupling degree (correlation coefficient) between every two coil elements of an array coil formed by the coil elements, thus improving the parallel transmission (pTX) performance and the uniformity of a magnetic resonance RF transmission field.

2. The loss circuit on-off element, the frequency compensation circuit, the impedance compensation circuit, the frequency compensation circuit on-off element and the impedance compensation circuit on-off element are also arranged in the RF coil element. When the coil is in a transmission state or a reception state, the loss circuit on-off element, the frequency compensation circuit on-off element and the impedance compensation circuit on-off element are controlled to be turned on or off to connect/disconnect the active loss circuit, the frequency compensation circuit and the impedance compensation circuit to/from the coil, so that a required resonance frequency and characteristic impedance can be obtained no matter whether the coil is in the transmission state or the reception state.

3. In the prior art, the area of coil elements is made very small to reduce the coupling between the elements during transmission. However, in the invention, the active loss circuit is arranged to reduce the coupling between the coil elements during transmission, so that the area of the coil elements does not need to be made small, and thus, the penetration capacity and penetration depth of the coil of the invention are significantly improved.

### BRIEF DESCRIPTION OF THE SEVERAL VIEWS OF THE DRAWINGS

FIG. 1 is a principle block diagram of a traditional RF coil;

FIG. 2 is a schematic circuit diagram of the traditional RF coil;

FIG. 3 is an equivalent circuit diagram of the traditional RF coil;

FIG. 4 is a schematic circuit diagram of a traditional RF receiver coil;

FIG. 5 is a schematic circuit diagram of a traditional ultrahigh-field RF transceiver array coil;

FIG. 6 is a coupling diagram of two identical coil elements;

FIG. 7 is a schematic diagram of the magnetic flux of overlap inductive decoupling of the two coil elements;

FIG. 8 is a schematic diagram of capacitive decoupling between the two coil elements;

FIG. 9 is an impedance analysis diagram of a resonance circuit of the right coil element in FIG. 8;

FIG. 10 is a schematic circuit diagram of an RF coil element in Embodiment 1 of the invention;

FIG. 11 is a schematic circuit diagram of an RF coil element in Embodiment 2 of the invention;

FIG. 12 is a schematic circuit diagram of an RF coil element in Embodiment 3 of the invention;

FIG. 13 is a schematic circuit diagram of an RF coil element in Embodiment 4 of the invention;

FIG. 14 is a schematic circuit diagram of an RF coil element in Embodiment 5 of the invention;

FIG. 15 is an equivalent circuit diagram of the RF coil element in a reception state in Embodiment 5 of the invention;

FIG. 16 is an equivalent circuit diagram of the RF coil element in a transmission state in Embodiment 5 of the invention;

FIG. 17 is a schematic circuit diagram of a transmitter-only coil element in Embodiment 6 of the invention;

FIG. 18 is a schematic circuit diagram of a transceiver coil element in Embodiment 7 of the invention;

FIG. 19 is a schematic circuit diagram of an RF coil element in Embodiment 8 of the invention;

FIG. 20 is a schematic circuit diagram of a traditional birdcage coil;

FIG. 21 is a schematic circuit diagram of a birdcage coil added with a loss circuit in Embodiment 9 of the invention;

FIG. 22 is a schematic circuit diagram of an 8-channel transceiver RF array coil in Embodiment 10 of the invention;

FIG. 23 is a diagram of an RF transmission field B1 of the array coil in Embodiment 10 of the invention;

FIG. 24 is a diagram of an RF transmission field B1 of a traditional solution.

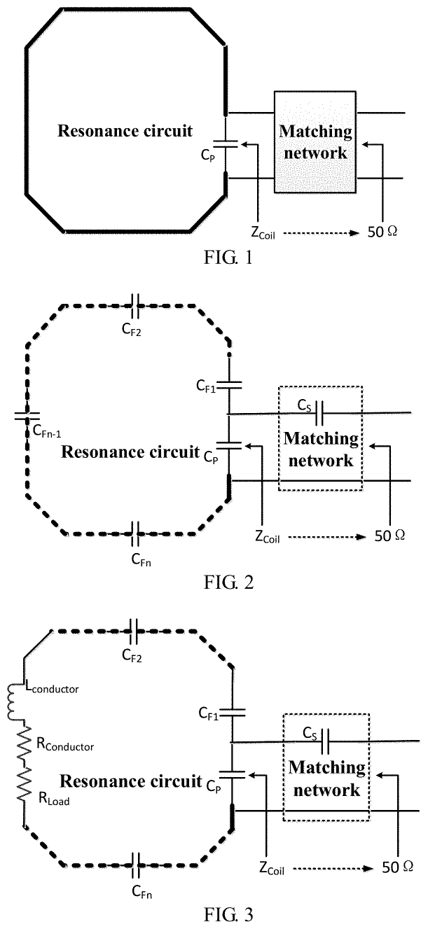

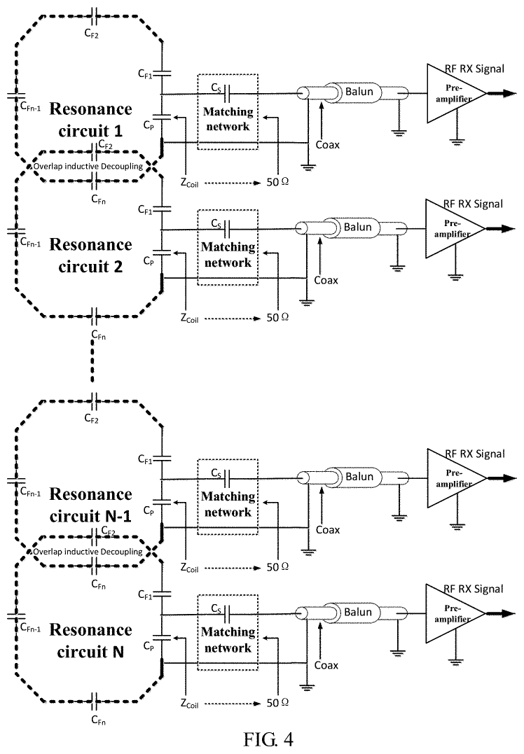

### DETAILED DESCRIPTION OF THE INVENTION

This application is further expounded below in combination with the embodiments and accompanying drawings. The invention can be implemented in various forms, and is not limited to the implementations described in the following embodiments. The following embodiments are provided for the purpose of a clearer and more comprehensive understanding of the contents of this application.

However, those skilled in the art would appreciate that one or more specific details in the following description can be omitted, or other methods, components, or materials can be adopted. In certain embodiments, some implementations are not described or not described in detail.

In addition, the technical characteristics and technical solutions in this description can be appropriately combined at random in one or more embodiments. It is appreciable for those skilled in the art that the sequence of steps or operations relating to the embodiments provided in this description can be changed. Thus, any sequences in the accompanying drawings and embodiments are only for the purpose of explanation, and do not, unless otherwise specifically stated, indicate that the steps or operations must be performed in certain sequences.

The serial numbers of components such as “first” and “second” in this description are only used for distinguishing the objects referred to, and do not have any sequential or technical indications.

### Embodiment 1

FIG. 10 shows the first embodiment of the RF coil element for magnetic resonance imaging of the invention (hereinafter referred to as coil element). Identical with traditional RF coil elements, the coil element of the invention also comprises a resonance circuit and a matching network connected with the resonance circuit. Wherein, the resonance circuit is a closed circuit which is formed by series connection of a plurality of (n) capacitors (FIG. 10 specifically shows five capacitors C_{P}, C_{H}, C_{F2}, C_{Fn-1}, and C_{Fn} constituting the resonance circuit) through a conductor (the conductor is typically a copper wire), and the matching network consists of a capacitor C_{S}.

The key improvement of this embodiment lies in that active loss circuits are additionally arranged in the RF coil element to actively dissipate and absorb the RF power in the RF coil element (namely to dissipate transmission energy of the coil element and to weaken a signal during reception of the coil) to decrease the Q value of the RF coil element (namely to reduce the sensitivity of the coil element). That is to say, the efficiency of the RF coil element during transmission is significantly reduced.

Particularly, two active loss circuits are arranged in the RF coil element, as shown in FIG. 10, wherein one active loss circuit R_{LOSS1} is connected to the RF resonance circuit and is particularly connected in parallel with the capacitor C_{F2} in the resonance circuit, and the other active loss circuit R_{LOSS2} is connected to the matching network.

It should be noted that in FIG. 10, the active loss circuit R_{LOSS1} is connected in parallel to two terminals of the capacitor C_{F2}, but the connection mode of the active loss circuit R_{LOSS1} to the radio-frequency circuit is not limited to the such mode, for example, the active loss circuit R_{LOSS1} may be connected in series with one capacitor in the resonance circuit optionally. The connection mode of the active loss circuit R_{LOSS2} to the matching network is not limited to the one shown in FIG. 10 either.

Clearly, it is also feasible to configure only one active loss circuit, and if this is the case, the active loss circuit is selectively connected to the resonance circuit or the matching network. Generally speaking, in the case where only one active loss circuit is configured, the active loss circuit is typically connected to the resonance circuit, that is, the active loss circuit is connected in series or in parallel with a circuit component in the resonance circuit.

It should be noted that in the case where the resonance circuit and the matching network of the coil element are not strictly marked off or even the matching network essentially belongs to the resonance circuit, it is impossible to definitely point out whether the active loss circuit is connected to the resonance circuit or the matching network. In another case where the impedance across the two terminals of the resonance circuit of some special coil elements is a characteristic impedance (such as 50Ω), it is unnecessary to configure a matching network, which means that such coil elements do not have a matching network. In these two cases, the active loss circuit can be connected to any feasible position of the coil element as long as the active loss circuit is able to actively dissipate and absorb the RF power in the RF coil element to decrease the Q value of the RF coil element.

When the RF coil element in the first embodiment is used to fabricate an RF coil for magnetic resonance imaging, particularly an array coil, the active loss circuits R_{LOSS1} and R_{LOSS2} additionally configured in the RF coil element are able to actively dissipate and absorb the RF power in the RF coil element to decrease the Q value of the RF coil element, that is, the efficiency of the RF coil element during transmission is reduced, so that the coupling degree between coil elements is decreased, thus improving the performance of the array coil used for transmission and particularly significantly improving the uniformity of the transmission field B1.

The active loss circuit R_{LOSS1} and R_{LOSS2} in FIG. 10 can be any structure forms capable of actively dissipating and absorbing the RF power in the RF coil element to decrease the Q value of the RF coil element, and all such circuit modules can be used as the active loss circuits to be applied to the coil element to improve the transmission performance of the coil and to improve the uniformity of the transmission field B1.

Particularly, in this embodiment, the active loss circuit R_{LOSS1} and the active loss circuit R_{LOSS2} shown in FIG. 10 are both resistors.

There are at least the following four types of common active loss circuits: 1, resistors in series or parallel connection with circuit components in the RF coil element; 2, low-Q-value components in series or parallel connection with circuit components in the RF coil element; 3, conductors, with a conductivity smaller than that of copper, in series or parallel connection with circuit components in the RF coil element; 4, equivalent resistor modules in series or parallel connection with circuit components in the RF coil element. Clearly, the active loss circuits may also be combinations of the resistors, low-Q-value components, low-conductivity conductors and equivalent resistor modules.

### Embodiment 2

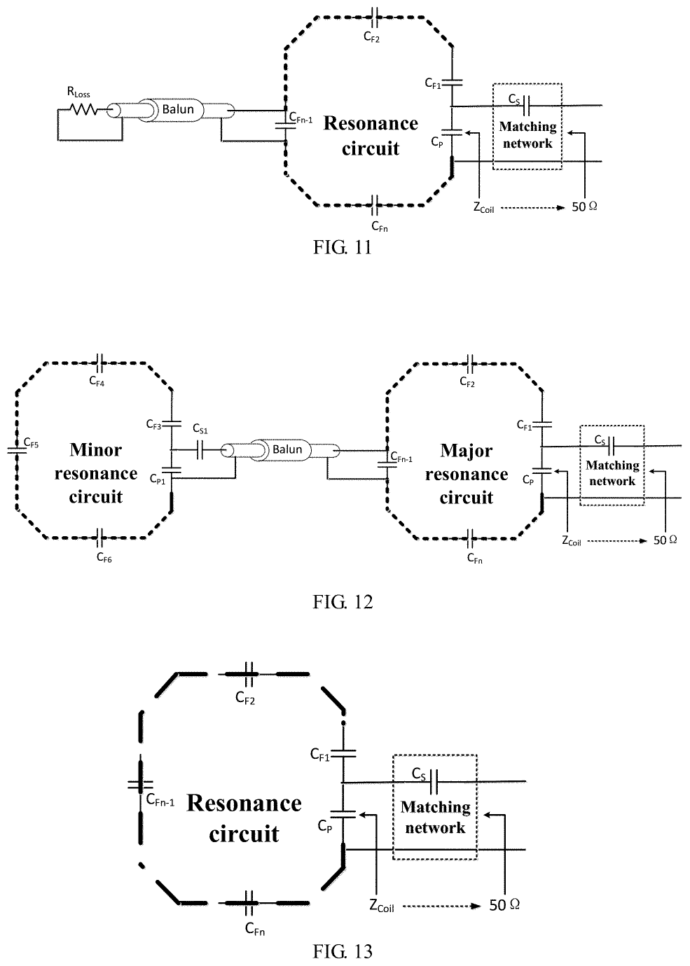

FIG. 11 shows a second embodiment of the RF coil element for magnetic resonance imaging of the invention. In this embodiment, the RF coil element for magnetic resonance imaging also comprises a resonance circuit and a matching network connected with the resonance circuit. Wherein, the resonance circuit is a closed circuit formed by series connection of a plurality of capacitors (FIG. 11 specifically shows five capacitors C_{P}, C_{F1}, C_{F2}, C_{Fn-1}, and C_{Fn} constituting the resonance circuit) through a conductor (the conductor is typically a copper wire), and the matching network consists of a capacitor C_{S}.

Identical with the first embodiment, an active loss circuit R_{LOSS} is particularly arranged in the RF coil element to dissipate and absorb the RF power in the RF coil element to decrease the Q value of the RF coil element.

Different from the first embodiment, one active loss circuit is arranged in the RF coil element in this embodiment, and the active loss circuit is arranged at a position away from the resonance circuit and is connected to a position away from the resonance circuit instead of being directly connected to the resonance circuit like the first embodiment.

Similarly, the active loss circuit R_{LOSS} in the second embodiment is able to actively dissipate and absorb the RF power in the RF coil element to decrease the Q value of the RF coil element, that is, the efficiency of the RF coil element during transmission is reduced. Thus, when the RF coil element in the second embodiment is used to fabricate an RF coil for magnetic resonance imaging, particularly an array coil, the coupling degree between coil elements in the array coil can be reduced, thus improving the performance of the array coil used for transmission and particularly significantly improving the uniformity of the transmission field B1.

### Embodiment 3

FIG. 12 shows a third embodiment of the RF coil element for magnetic resonance imaging of the invention, and the RF coil element in this embodiment also comprises a resonance circuit and a matching network connected with the resonance circuit. Wherein, the resonance circuit is a closed circuit formed by series connection of n capacitors (FIG. 12 specifically shows five capacitors C_{P}, C_{H}, C_{F2}, C_{Fn-1}, and C_{Fn} constituting the resonance circuit) through a conductor (the conductor is typically a copper wire), and the matching network consists of a capacitor C_{S}.

Identical with the second embodiment, an active loss circuit R_{LOSS} is particularly arranged in the RF coil element to actively dissipate and absorb the RF power in the RF coil element to decrease the Q value of the RF coil element, and the active loss circuit R_{LOSS} is arranged at a position away from the resonance circuit and is connected to a position away from the resonance circuit.

Different from the second embodiment, the active loss circuit R_{LOSS} in this embodiment is a secondary resonance circuit (the secondary resonance circuit is equivalent to a resistor connected in parallel to two terminals of C_{Fn-1}, thus being referred to as an equivalent resistor module or a resistance generation circuit) arranged at a position away from the resonance circuit instead of a simple resistor element. Obviously, the secondary resonance circuit in FIG. 12 is able to actively dissipate and absorb the RF power in the RF coil element to decrease the Q value of the RF coil element.

Similarly, the active loss circuit R_{LOSS} in the third embodiment is able to actively dissipate and absorb the RF power in the RF coil element to decease the Q value of the RF coil element, that is, the active loss circuit R_{LOSS} is able to reduce the efficiency of the RF coil element during transmission. Thus, when the RF coil element in the third embodiment is used to fabricate an RF coil for magnetic resonance imaging, particularly an array coil, the coupling degree between coil elements in the array coil can be decreased, thus, improving the performance of the array coil used for transmission and particularly significantly improving the uniformity of the transmission field B1.

### Embodiment 4

FIG. 13 shows a fourth embodiment of the RF coil element for magnetic resonance imaging of the invention, and the RF coil element in this embodiment also comprises a resonance circuit and a matching network connected with the resonance circuit. Wherein, the resonance circuit is a closed circuit formed by series connection of a plurality of capacitors (FIG. 13 specifically shows five capacitors C_{P}, C_{F1}, C_{F2}, C_{Fn-1}, and C_{Fn} constituting the resonance circuit) through a conductor (the conductor is typically a copper wire), and the matching network consists of a capacitor C_{S}.

In this embodiment, an active loss circuit is particularly arranged in the RF coil element to actively dissipate and absorb the RF power in the RF coil element to decrease the Q value of the RF coil element.

Different from the first embodiment, the second embodiment and the third embodiment, the conductor used for series connection of the capacitors (including C_{P}, C_{F2}, C_{Fn-1}, and C_{Fn}) is a conductor with a conductivity lower than that of copper instead of a traditional copper wire. In this embodiment, the conductor is specifically an aluminum wire.

Obviously, the replacement of a traditional copper wire with the aluminum wire with a lower conductivity is equivalent to series connection of a small-resistance resistor to the resonance circuit, so that the RF power in the RF coil element can be actively dissipated and absorbed to decrease the Q value of the RF coil element.

Similarly, the active loss circuit in the fourth embodiment is able to actively dissipate and absorb the RF power in the RF coil element to decease the Q value of the RF coil element, that is, the active loss circuit R_{LOSS} is able to reduce the efficiency of the RF coil element during transmission. Thus, when the RF coil element in the fourth embodiment is used to fabricate an RF coil for magnetic resonance imaging, particularly an array coil, the coupling degree between coil elements in the array coil can be decreased, thus, improving the performance of the array coil used for transmission and particularly significantly improving the uniformity of the transmission field B1.

### Embodiment 5

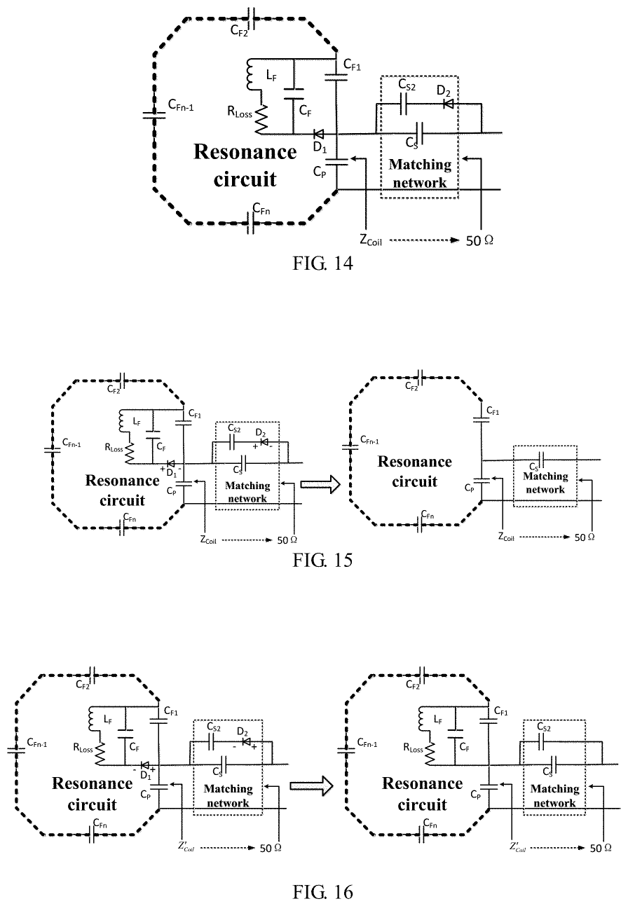

FIG. 14 shows a fifth embodiment of the RF coil element for magnetic resonance imaging of the invention, and the RF coil element in this embodiment also comprises a resonance circuit and a matching network connected with the resonance circuit. Wherein, the resonance circuit is a closed circuit formed by series connection of a plurality of capacitors (FIG. 14 specifically shows five capacitors C_{P}, C_{F1}, C_{F2}, C_{Fn-1}, and C_{Fn} constituting the resonance circuit) through a conductor (the conductor is typically a copper wire), and the matching network consists of a capacitor C_{S}.

In this embodiment, an active loss circuit R_{LOSS} is particularly arranged in the RF coil element to actively dissipate and absorb the RF power in the RF coil element to decrease the Q value of the RF coil element.

As can be known from the above description, the active loss circuit connected to the RF coil element in the first, second, third and fourth embodiments is able to actively dissipate and absorb the RF power in the RF coil element to decrease the Q value of the RF coil element, that is, the active loss circuit is able to reduce the efficiency of the RF coil element during transmission. Thus, when the RF coil element is used to fabricate an RF coil for magnetic resonance imaging, particularly an array coil, the coupling degree between coil elements in the array coil can be decreased, thus, improving the performance of the array coil used for transmission and particularly significantly improving the uniformity of the transmission field B1.

However, in the aforesaid five embodiments, the active loss circuit added to the RF coil element is only able to improve the performance of the RF coil element used for transmission (to reduce the coupling degree). However, when the RF coil element is used for reception, the active loss circuit still absorbs the RF power in the RF coil element to decrease the Q value of the RF coil element, which in turn reduces the efficiency of the RF coil element used for reception (the reception efficiency is drastically reduced), and this is undesired. The reception efficiency (signal to noise ratio of reception) is the first factor that should be taken into consideration during reception, and the coupling degree can be decreased by configuration of a pre-amplifier. So, the active loss circuit added to the RF coil element may reduce the most important reception performance, namely the signal to noise ratio of reception, of the coil. It is completely fine to apply the RF coil element to an RF transmitter array coil which does not involve reception because there is no problem about the reduction of the reception efficiency in this case. However, if the RF coil element is applied to an RF transceiver array coil, the reception efficiency of the coil will be drastically reduced inevitably during reception, which in turn results in blurred magnetic resonance images.

In order to solve this problem, an ingenuous solution is provided in the fifth embodiment: referring to FIG. 14, a diode D1 in series connection with the active loss circuit R_{LOSS} is configured; when the coil element is used for transmission, the diode D1 is turned on, the active loss circuit R_{LOSS} is connected to the coil element (the active loss circuit R_{LOSS} is turned on), and in this case, the transmission uniformity focused by users is improved. When the coil element is used for reception, the diode D1 is turned off, the active loss circuit R_{LOSS} is turned off accordingly (the active loss circuit R_{LOSS} is not connected to the coil element), so that the reception efficiency focused by users will not be reduced in spite of the presence of the active loss circuit R_{LOSS}.

Clearly, the diode D1 can be replaced with other components which are able to turn on the active loss circuit R_{LOSS} when the coil is used for transmission and to turn off active loss circuit R_{LOSS} when the coil is used for reception, and such components (such as the diode D1 in FIG. 14) are referred to as loss circuit on-off elements.

Because the active loss circuit R_{LOSS} is turned on when the coil is used for transmission and is turned off when the coil is used for reception, the resonance circuit of the coil element have different frequencies and impedances during transmission and reception, while the structure of the matching network is constant during transmission and reception, and thus, magnetic resonance images cannot be acquired easily. In view of this, the structure of the coil element is further improved in the fifth embodiment particularly as follows:

In the fifth embodiment, a frequency compensation circuit, an impedance compensation circuit, a frequency compensation circuit on-off element used to turn on/off the frequency compensation circuit, and an impedance compensation circuit on-off element used to turn on/off the impedance compensation circuit are also configured in the RF coil element, wherein the frequency compensation circuit is specifically connected to the resonance circuit of the coil element, and the impedance compensation circuit is specifically connected to the matching network.

Generally speaking, when the coil element is used for transmission, the loss circuit on-off element, the frequency compensation circuit on-off element and the impedance compensation circuit on-off element are all turned on to allow the active loss circuit, the frequency compensation circuit and the impedance compensation circuit to be connected to the coil element; and when the coil element is used for reception, the loss circuit on-off element, the frequency compensation circuit on-off element and the impedance compensation circuit on-off element are all turned off to disconnect the active loss circuit, the frequency compensation circuit and the impedance compensation circuit from the coil element. In this way, the resonance frequency and impedance (characteristic impedance, generally 50Ω) are kept consistent when the coil element is used for reception and transmission, and clear magnetic resonance images are obtained.

More particularly, as shown in FIG. 14, the active loss circuit R_{LOSS} and the diode D1 which are in series connection are further connected in series with an inductor L_{F}. Two terminals of the active loss circuit R_{LOSS}, the diode D₁ and the inductor L_{F} which are connected in series are connected in parallel with the capacitor C_{H}, and two terminals of the active loss circuit R_{LOSS} and the diode D₁ are connected in parallel with the capacitor C_{F}. Herein, the inductor L_{F} and the capacitor C_{F} constitute the frequency compensation circuit, the diode D₁ constitutes the frequency compensation circuit on-off element and the loss circuit on-off element. In addition, a capacitor C_{S2} and a diode D₂ are additionally configured in the matching network, wherein after the capacitor C_{S2} and the diode D₂ are connected in series, two terminals (namely two terminals of the capacitor C_{S2} and the diode D₂) are connected in parallel with the capacitor C_{S} in the matching network. Herein, the capacitor C_{S2} constitutes the impedance compensation circuit, and the diode D₂ constitutes the impedance compensation circuit on-off element.

When the coil element is used for transmission, the diode D₁ and the diode D₂ are turned on to allow the active loss circuit R_{LOSS} and the frequency compensation circuit (the inductor L_{F} and the capacitor C_{F}) and the impedance compensation circuit (the capacitor C_{S2}) to be connected to the coil element, and at this moment, the whole equivalent circuit of the coil element is shown in FIG. 16. In this case, the capacitor C_{S2} is connected to the matching network to participate in impedance matching and is regarded as a constituent part of the matching network; and the active loss circuit R_{LOSS} is connected to the resonance circuit to participate in resonance and is regarded as a constituent part of the resonance circuit.

When the coil element is used for reception, the diode D₁ and the diode D₂ are turned off to disconnect the active loss circuit R_{LOSS} and the frequency compensation circuit (the inductor L_{F} and the capacitor C_{F}) and the impedance compensation circuit (the capacitor C_{S2}) from the coil element, and as shown in FIG. 15, the whole equivalent circuit of the coil element at this moment is equivalent to an original (traditional) coil element. During transmission, the resonance frequency of the resonance circuit will be changed due to the presence of the active loss circuit R_{LOSS}, while the inductor L_{F} and the capacitor C_{F} can compensate for a deviation of the resonance frequency. In addition, although the impedance of the coil turns into Z′_{Coil}, the capacitor C_{S} used for reception is replaced with the capacitor C_{S} and the capacitor C_{S2} which are connected in parallel in the matching network, so that Z′_{Coil} still matches the characteristic impedance 50Ω. In this case, the capacitor C_{S2} is not connected to the matching network and does not participate in impedance matching, and the active loss circuit R_{LOSS} is not connected to the resonance circuit and does not participate in resonance.

That is to say, as long as the corresponding relationship among the active loss circuit R_{LOSS}, the inductor L_{F} and the capacitor C_{F} is properly designed, the resonance frequency and characteristic impedance can be kept consistent (matching) both in the reception stage and in the transmission stage of the coil element.

It should be noted that the frequency compensation circuit and the impedance compensation circuit are not limited to the specific structure forms shown in FIG. 14, any circuits (various circuit components in the coil element) that are able to keep the resonance frequency matching the characteristic impendence during transmission and reception can be used as the frequency compensation circuit and the impedance compensation circuit. For example, in FIG. 14, the capacitor C_{F} connected in parallel to the two terminals of the active loss circuit R_{LOSS} and the capacitor C_{F} can be removed, and in this case, the frequency compensation circuit is formed by the inductor L_{F} only. The capacitor C_{F} is connected in parallel to the two terminals of the active loss circuit R_{LOSS} and the capacitor C_{F} in the fifth embodiment for the purpose of easier control during adjustment for frequency compensation.

It should be noted that the matching network may be of various structures. In certain embodiments, the matching network further includes an inductor, and in this case, the impedance compensation circuit can be selectively connected in parallel to the two terminals of the inductor of the matching network.

### Embodiment 6

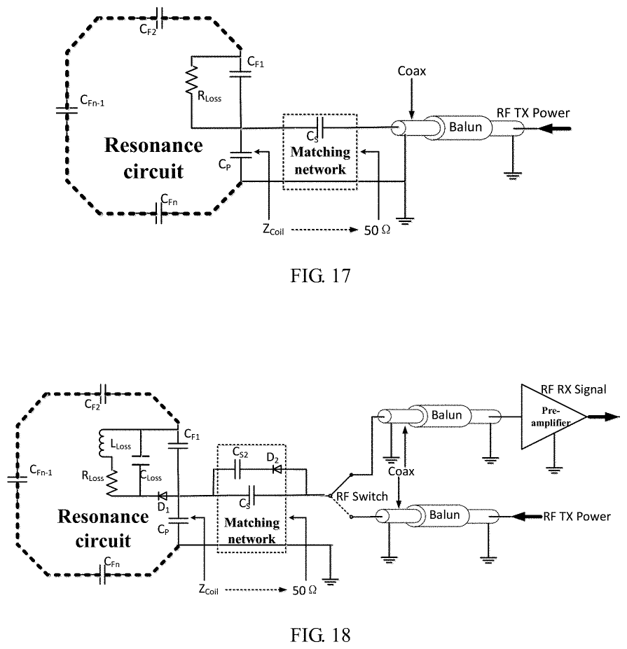

When the coil element shown in FIG. 14 is used for transmission only (for example, the coil element is applied to a transmitter-only array coil) that does not involve state switching, and the diode D₁, the diode D₂, the inductor L_{F}, the capacitor C_{F} and the impedance compensation circuit (capacitor C_{S2}) can be removed. On the basis of the RF coil element shown in FIG. 14, the transceiver-only coil element shown in FIG. 17 can be obtained by necessary RF-Trap (Balun) and RF amplifier power feed.

### Embodiment 7

On the basis of the coil element shown in FIG. 14, an RF transceiver array coil element can be obtained by the addition of a high-power RF switch, necessary Balun and a pre-amplifier used for reception. The circuit structure of the RF transceiver array coil element is shown in FIG. 18.

The working principle of the coil element shown in FIG. 18 is as follows:

When a magnetic resonance system is in an RF transmission state, the RF switch is switched to a transmission link, two RF diodes (D₁ and D₂) are turned on, at this moment, the capacitor C_{S} and the capacitor C_{S2} which are connected in parallel in the matching network are turned on to regulate the impedance Z′_{coil} generated by the resonance circuit to the characteristic impedance 50Ω, and the RF amplifier and the coil element are in a good power matching condition.

When the magnetic resonance circuit is in an RF reception state, the RF switch is switched to a reception link, the two RF diodes (D₁ and D₂) are turned off, at this moment, the capacitor C_{S} in the matching network regulates the impedance Z′_{Coil} generated by the resonance circuit to the characteristic impedance 50Ω, and the pre-amplifier and the coil element are in a good noise matching condition.

In conclusion, no matter whether the coil element is in a transmission state or a reception state, the coil element is in a good power matching or noise matching condition. In the transmission state, the sensitivity of the coil element is drastically reduced due to the presence of the active loss circuit R_{LOSS}, so that the coupling between coil elements can be reduced during transmission.

### Embodiment 8

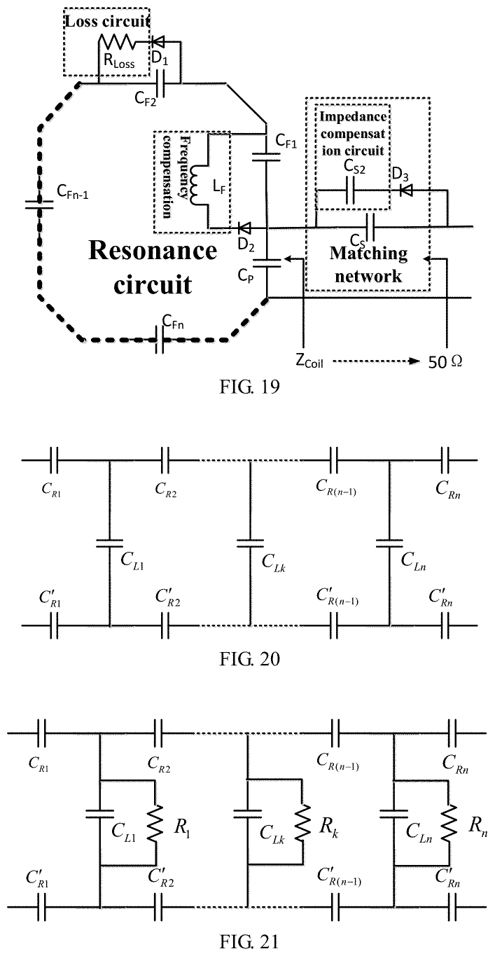

FIG. 19 shows another embodiment of the RF coil element for magnetic resonance imaging of the invention. In this embodiment, the RF coil element for magnetic resonance imaging also comprises a resonance circuit and a matching network connected with the resonance circuit, wherein the resonance circuit is a closed circuit formed by series connection of a plurality of capacitors (FIG. 19 specifically shows five capacitors C_{P}, C_{F1}, C_{F2}, C_{Fn-1}, and C_{Fn} constituting the resonance circuit) through a conductor (the conductor is typically a copper wire), and the matching network consists of a capacitor C_{S}.

In this embodiment, an active loss circuit R_{LOSS} is particularly arranged in the RF coil element to actively dissipate and absorb RF power in the RF coil element to decrease the Q value of the RF coil element. The active loss circuit R_{LOSS} is connected in parallel to two terminals of the capacitor C_{F2} in the resonance circuit.

On the basis of the same consideration as the fifth embodiment, a loss circuit on-off element used to control the active loss circuit R_{LOSS} to be turned on/off, a frequency compensation circuit, an impedance compensation circuit, a frequency compensation circuit on-off element used to turn on/off the frequency compensation circuit, and an impedance compensation circuit on-off element used to turn on/off the impedance compensation circuit are arranged in the RF coil element, wherein the frequency compensation circuit is specifically connected to the resonance circuit of the coil element, and the impedance compensation circuit is specifically connected to the matching network.

The structural forms of the loss circuit on-off element, the frequency compensation circuit, the impedance compensation circuit, the frequency compensation circuit on-off element and the impedance compensation circuit on-off element in this embodiment are completely different from those in the fifth embodiment. Particularly, in this embodiment, the active loss circuit R_{LOSS} is connected in series with a diode D₁ and is then connected in parallel with the capacitor C_{F2} in the resonance circuit, an inductor L_{F} is connected in series with another diode D₂ and is then connected in parallel with the capacitor C_{F1} in the resonance circuit, and a capacitor C_{S2} is connected in series with another diode D3 and is then connected in parallel with the capacitor C_{S} in the matching network. Appreciably, the inductor L_{F} in parallel connection with the capacitor C_{F2} constitutes the frequency compensation circuit, the capacitor C_{S2} in parallel connection with the capacitor C_{S} constitutes the impedance compensation circuit, the diode D₁ in series connection with the active loss circuit R_{LOSS} constitutes the loss circuit on-off element, the diode D₂ in series connection with the inductor L_{F} constitutes the frequency compensation circuit on-off element, and the diode D3 in series connection with the capacitor C_{S2} constitutes the impedance compensation circuit on-off element.

### Embodiment 9

Different from array coils, birdcage coils have no distinct element concept or distribution, and have a corresponding port concept. The principle of the invention is also applicable to the birdcage coils (not matter how many ports are configured).

The circuit principle of a traditional birdcage coil (one structural form of RF coils) is shown in FIG. 20, wherein CR represents capacitors at terminal rings, and CL represents capacitors on the legs.

FIG. 21 shows a birdcage coil improved by the inventor of this application. As shown in FIG. 21, a corresponding active loss circuit is connected in parallel to two terminals of the capacitors on the ring legs of the birdcage coils, R₁ is connected in parallel to the two terminals of C_{L1}, R_{K} is connected in parallel to the two terminals of CLK, and Rₙ is connected in parallel to the two terminals of C_{Ln}. The active loss circuits can also be arranged on a terminal ring circuit.

The active loss circuits R₁, R_{K}, and Rₙ are able to actively dissipate and absorb RF power in the birdcage coil to decrease the Q value of the birdcage coil, that is, the active loss circuits R₁, R_{K}, and Rₙ significantly reduce the efficiency of the birdcage coil during transmission. Similarly, the coupling between the ports can be effectively reduced, thus effectively improving the transmission performance of the birdcage coil.

### Embodiment 10

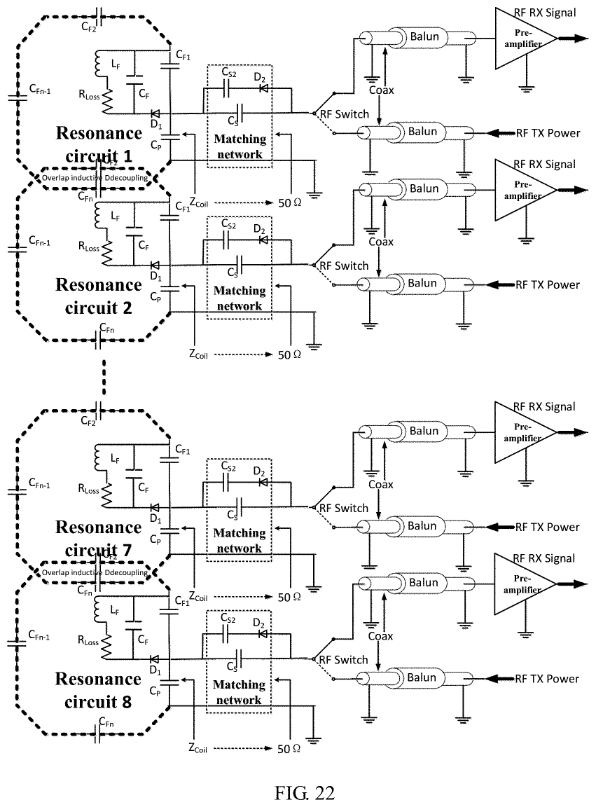

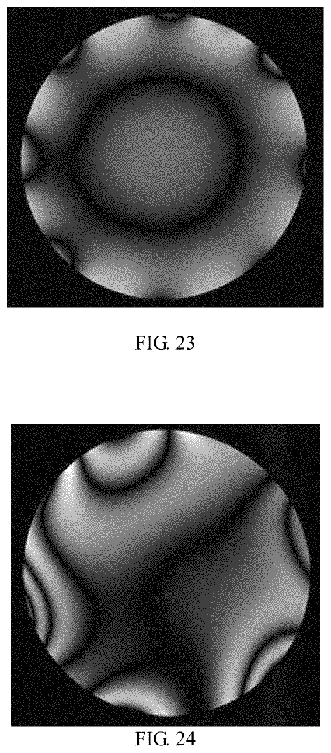

Referring to FIG. 22, the technical solution of the invention is introduced in detail below with an 8-channel transceiver RF array coil as an example.

The 8-channel transceiver RF array coil in this embodiment adopts 8 coil elements mentioned in the seventh embodiment (FIG. 18), and every two adjacent coil elements overlap partially. It should be noted that the coil in this embodiment is a cylindrical coil, and the 8 coil elements are adjacently arrayed end-to-end around a cylinder to form the array coil, that is, the element 1 and the element 8 also overlap partially.

In order to verify the validity of the patent, this embodiment is subjected to a comparative test in a Siemens Verio 3.0T system. FIG. 23 shows specific results of this embodiment, and FIG. 24 shows test results of a traditional 8-channel transceiver coil. The quantity and shape (symmetry) of black stripes in the figures reflect the uniformity of the RF transmission field. As can be seen from the test results, the uniformity of the transmission field B1 in this embodiment is significantly improved.

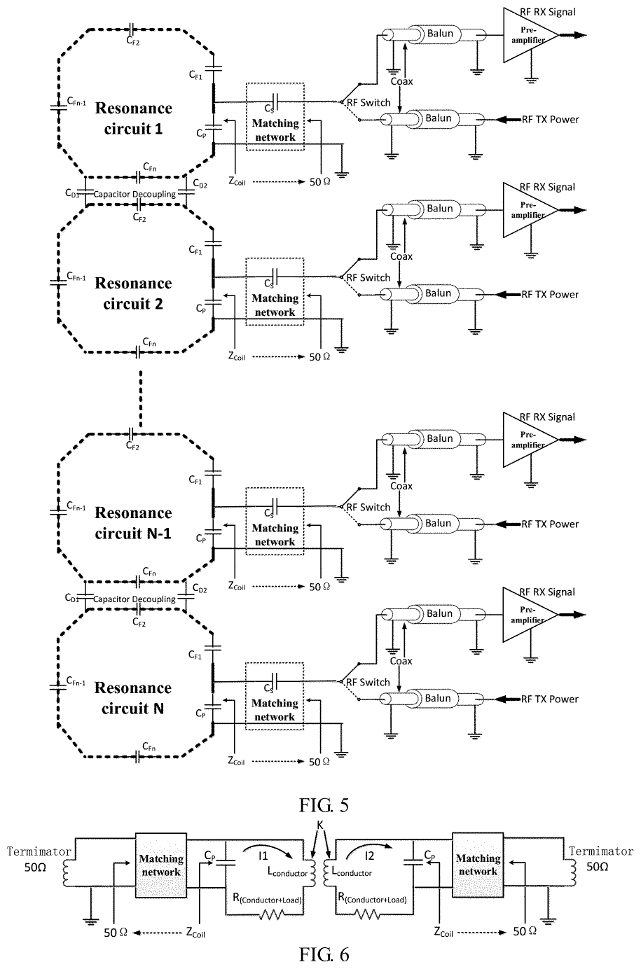

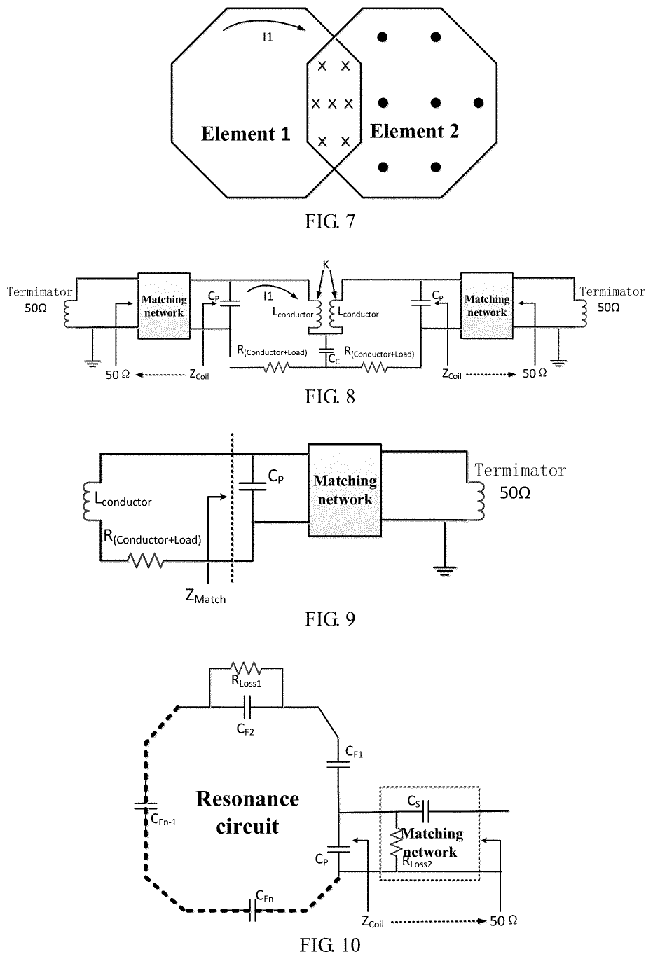

Compared with the existing common array coil shown in FIG. 5, the transceiver RF array coil in this embodiment has the following advantages and disadvantages:

1. Coupling between the elements during transmission: when the coil is in a transmission state, the Q value and the sensitivity of the coil element are drastically reduced due to the present of the active loss circuit R_{LOSS}, so that the coupling between elements is greatly reduced.

2. Transmission efficiency of the coil: because the Q value of the resonance circuit and the sensitivity of the coil element are drastically reduced, the transmission efficiency of the coil is also drastically reduced; however, the coil in this patent is generally used for multi-channel transmission during which multiple RF power amplifiers work synchronously, so that the requirement for the output power of each RF power amplifier is low, and common commercial RF power amplifiers can meet the requirement.

3. The uniformity of the transmission field: in the transmission state, the sensitivity of each element is reduced due to the presence of the active loss circuit R_{LOSS}, and the coupling between the coil elements is greatly reduced, thus guaranteeing that the matching and sensitivity of the elements are highly consistent and remarkably improving the uniformity of the transmission field.

4. The stability of the transmission field: in the traditional design, the coil element with a high sensitivity is very sensitive to a load during transmission, and the transmission field may severely fluctuate due to load fluctuations. However, in this patent, the sensitivity of each element is reduced by the active loss circuit R_{LOSS}, the fluctuation caused by load fluctuations is reduced accordingly, and thus, the stability and consistency of the transmission field under different load conditions are improved.

5. Parallel transmission (pTX) performance: because the pTX performance is highly related to the coupling between the elements, the pTX performance will be improved accordingly by reduction of the coupling between the elements.

6. Coupling during reception: when the coil is in the reception state, the active loss circuit RLoss is disconnected from the resonance circuit, the Q value of the resonance circuit and the sensitivity of the coil element are increased to the existing common coil level, and the coupling degree is increased accordingly. In the reception state, the coupling is generally acceptable under the effect of pre-amp decoupling.

7. Signal to noise ratio during reception: because of the pre-amp decoupling function, the signal to noise ratio during reception is not affected in this embodiment.

8. Penetration capacity during reception: as shown in FIG. 5, in order to reduce the coupling between elements during transmission, the area of the element is much smaller than the area of the element in this embodiment, and thus, the penetration capacity and depth of the coil in this embodiment are significantly improved.

The invention further has various other embodiments. All technical solutions obtained by means of equivalent substitutions or transformations should also fall within the protection scope of the invention.

1. An RF coil element for magnetic resonance imaging, being connected with an active loss circuit which is able to actively dissipate and absorb RF power in the RF coil element to decrease a Q value of the coil element.

2. The RF coil element for magnetic resonance imaging according to claim 1, wherein the active loss circuit is a resistor in series or parallel connection with a circuit component in the RF coil element.

3. The RF coil element for magnetic resonance imaging according to claim 1, wherein the active loss circuit is a low-Q-value component in series or parallel connection with a circuit component in the RF coil element.

4. The RF coil element for magnetic resonance imaging according to claim 1, wherein the active loss circuit is a conductor, with a conductivity smaller than that of copper, in series connection with a circuit component in the RF coil element.

5. The RF coil element for magnetic resonance imaging according to claim 1, wherein the active loss circuit is an equivalent resistor module in series or parallel connection with a circuit component in the RF coil element.

6. The RF coil element for magnetic resonance imaging according to claim 1, wherein a loss circuit on-off element used to turn on/off the active loss circuit is connected to the coil element.

7. The RF coil element for magnetic resonance imaging according to claim 6, wherein the coil element is also connected with:
a frequency compensation circuit,
an impedance compensation circuit,
a frequency compensation circuit on-off element used to turn on/off the frequency compensation circuit, and
an impedance compensation circuit on-off element used to turn on/off the impedance compensation circuit.

8. The RF coil element for magnetic resonance imaging according to claim 7, wherein the coil element comprises a resonance circuit and a matching network connected with the resonance circuit, wherein the active loss circuit is in series or parallel connection with a circuit component in the resonance circuit or the matching network, the frequency compensation circuit is in series or parallel connection with a circuit component in the resonance circuit, and the impedance compensation circuit is in series or parallel connection with a circuit component in the matching network.

9. The RF coil element for magnetic resonance imaging according to claim 8, wherein the resonance circuit is a closed circuit formed by series connection of one or more conductors and one or more capacitors, and the matching network comprises a capacitor or an inductor.

10. The RF coil element for magnetic resonance imaging according to claim 9, wherein the resonance circuit comprises at least two capacitors which are connected in series, the active loss circuit is connected in series with a first diode and is then connected in parallel with one said capacitor in the resonance circuit, a first inductor is connected in series with a second diode and is then connected in parallel with the other capacitor in the resonance circuit, the first diode constitutes the loss circuit on-off element, and the second diode constitutes the frequency compensation circuit on-off element.

11. The RF coil element for magnetic resonance imaging according to claim 9, wherein the active loss circuit is connected in series with a second inductor and a third diode and is then connected in parallel with one said capacitor in the resonance circuit, the second inductor constitutes the frequency compensation circuit, and the third diode constitutes the frequency compensation circuit on-off element and the loss circuit on-off element.

12. The RF coil element for magnetic resonance imaging according to claim 11, wherein two terminals of the active loss circuit and the second inductor are connected in parallel with a first capacitor, and the second inductor and the first capacitor constitute the frequency compensation circuit jointly.

13. The RF coil element for magnetic resonance imaging according to claim 9, wherein a second capacitor is connected in series with a fourth diode and is then connected in parallel with the capacitor or inductor in the matching network, the second capacitor constitutes the impedance compensation circuit, and the fourth diode constitutes the impedance compensation circuit on-off element.

14. An RF coil for magnetic resonance imaging, being an array coil, wherein the RF coil comprises at least one RF coil element according to claim 1.

15. The RF coil for magnetic resonance imaging according to claim 14, wherein the RF coil is a transceiver-only RF array coil, a receiver-only RF array coil, or a transceiver RF array coil.

16. An RF coil for magnetic resonance imaging, being a birdcage coil, wherein an active loss circuit is connected to the RF coil to actively dissipate and absorb RF power in the RF coil to decrease the Q value of the coil.

17. The RF coil for magnetic resonance imaging according to claim 16, wherein the active loss circuit is connected in series or parallel with a capacitor on a leg or terminal ring in the RF coil.

18. The RF coil element for magnetic resonance imaging according to claim 8, the active loss circuit is arranged at a position away from the resonance circuit and is connected to a position away from the resonance circuit.
